(19) United States
(12) Patent Application Publication
(10) Pub. No.: US 2007/0212801 A1
(43) Pub. Date: Sep. 13, 2007

(54) System for adjusting manufacturing equipment, method for adjusting manufacturing equipment, and method for manufacturing semiconductor device

(76) Inventors: Masahiro Kanno, Yokohama-shi (JP); Masafumi Asano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/708,344

(22) Filed: Feb. 21, 2007

(30) Foreign Application Priority Data
Feb. 22, 2006 (JP) P2006-045923

(51) Int. Cl. H01L 21/66; G06F 19/00

(52) U.S. Cl. 438/14; 438/16; 700/114

(57) ABSTRACT

A system for adjusting a manufacturing equipment includes a measurement equipment configured to measure a plurality of sizes of portions of a product on a plane, an approximation module configured to approximate a planar distribution of the plurality of sizes by an orthogonal polynomial. as a function of coordinates on the plane, an association module configured to associate a plurality of terms in the orthogonal polynomial with a plurality of equipment parameters of the manufacturing equipment, respectively, the manufacturing equipment manufacturing the product, and an adjusting module configured to adjust the plurality of equipment parameters to reduce a plurality of distribution components, the plurality of distribution components composing the planar distribution approximated by the orthogonal polynomial.

### CROSS REFERENCE TO RELATED APPLICATIONS AND INCORPORATION BY REFERENCE

This application is based upon and claims the benefit of priority from prior Japanese Patent Application P2006-045923 filed on Feb. 22, 2006; the entire contents of which are incorporated by reference herein.

### BACKGROUND OF THE INVENTION

1. Field of the Invention

The present invention relates to production engineering and in particular to a system for adjusting a manufacturing equipment, a method for adjusting the manufacturing equipment, and a method for manufacturing a semiconductor device.

2. Description of the Related Art

As described in Japanese Patent Laid-Open Publication No. 2004-179663, when a semiconductor device is manufactured, sizes of a circuit pattern formed on a silicon wafer may vary, depending on various factors. Especially, when a large silicon wafer, such as 300 mm wafer, is used, the sizes of the circuit pattern formed on the silicon wafer tend to vary. As the result, the yield rate of the semiconductor device becomes low and a manufacturing time is protracted. Therefore, it has been necessary to measure the sizes of the circuit pattern formed on the silicon wafer and work out measures to unify the planar distribution of the sizes.

### SUMMARY OF THE INVENTION

An aspect of present invention inheres in a system for adjusting a manufacturing equipment, according to an embodiment of the present invention. The system includes a measurement equipment configured to measure a plurality of sizes of portions of a product on a plane, an approximation module configured to approximate a planar distribution of the plurality of sizes by an orthogonal polynomial as a function of coordinates on the plane, an association module configured to associate a plurality of terms in the orthogonal polynomial with a plurality of equipment parameters of the manufacturing equipment, respectively, the manufacturing equipment manufacturing the product, and an adjusting module configured to adjust the plurality of equipment parameters to reduce a plurality of distribution components. The plurality of distribution components compose the planar distribution approximated by the orthogonal polynomial.

Another aspect of the present invention inheres in a method for adjusting the manufacturing equipment, according to the embodiment of the present invention. The method includes measuring a plurality of sizes of portions of a product on a plane, approximating a planar distribution of the plurality of sizes by an orthogonal polynomial as a function of coordinates on the plane, associating a plurality of terms in the orthogonal polynomial with a plurality of equipment parameters of the manufacturing equipment, respectively, the manufacturing equipment manufacturing the product, and adjusting the plurality of equipment parameters to reduce a plurality of distribution components. The plurality of distribution components compose the planar distribution approximated by the orthogonal polynomial.

Yet another aspect of the present invention inheres in method for manufacturing a semiconductor device, according to the embodiment of the present invention. The method for manufacturing the semiconductor device includes measuring a plurality of sizes of portions of a product on a plane, approximating a planar distribution of the plurality of sizes by an orthogonal polynomial as a function of coordinates on the plane, associating a plurality of terms in the orthogonal polynomial with a plurality of equipment parameters of the manufacturing equipment, respectively, the manufacturing equipment manufacturing the product, adjusting the plurality of equipment parameters to reduce a plurality of distribution components composing the planar distribution approximated by the orthogonal polynomial, and manufacturing the semiconductor device by the manufacturing equipment of which the plurality of equipment parameters are adjusted.

### BRIEF DESCRIPTION OF DRAWINGS

FIG. 1 is a diagram of a system for adjusting the manufacturing equipment in accordance with a first embodiment of the present invention;

FIG. 2 illustrates an exposure tool in accordance with the first embodiment of the present invention;

FIG. 3 is a first plan view of a polarizer in accordance with the first embodiment of the present invention;

FIG. 4 is a second plan view of the polarizer in accordance with the first embodiment of the present invention;

FIG. 5 is a pattern diagram showing a planar distribution of sizes of portions of a product on a wafer in accordance with the first embodiment of the present invention;

FIG. 6 is a first pattern diagram showing a distribution component composing the planar distribution in accordance with the first embodiment of the present invention;

FIG. 7 is a second pattern diagram showing the distribution component composing the planar distribution in accordance with the first embodiment of the present invention;

FIG. 8 is a third pattern diagram showing the distribution component composing the planar distribution in accordance with the first embodiment of the present invention;

FIG. 9 is a fourth pattern diagram showing the distribution component composing the planar distribution in accordance with the first embodiment of the present invention;

FIG. 10 is a fifth pattern diagram showing the distribution component composing the planar distribution in accordance with the first embodiment of the present invention;

FIG. 11 is a flowchart depicting a method for adjusting the manufacturing equipment in accordance with the first embodiment of the present invention.

FIG. 12 is a diagram of the system for adjusting the manufacturing equipment in accordance with a second embodiment of the present invention; and

FIG. 13 is a flowchart depicting the method for adjusting the manufacturing equipment in accordance with the second embodiment of the present invention.

### DETAILED DESCRIPTION OF THE INVENTION

Embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### FIRST EMBODIMENT

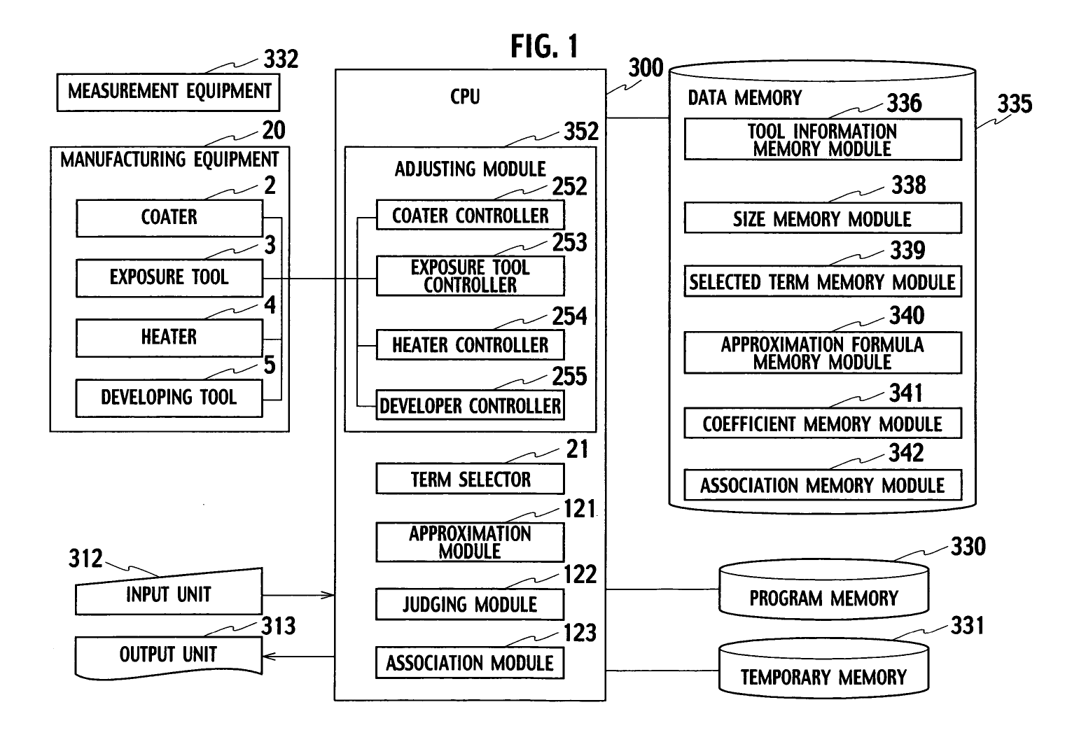

With reference to FIG. 1, a system for adjusting a manufacturing equipment, according to the first embodiment, includes a measurement equipment 332 configured to measure each size of a plurality of portions of a product on a plane and a central processing unit (CPU) 300. Here, “each size of portions of the product” means each depth of a plurality of trenches provided on a wafer such as a semiconductor substrate, each thickness of portions of a resist layer, an insulating layer, and a conductive layer on the semiconductor substrate, and each line width of portions of a resist pattern formed on the semiconductor substrate, for example. In the first embodiment, each line width of the portions of the resist pattern formed on the semiconductor substrate is took up as each size of the portions of the product.

The CPU 300 of the system for adjusting the manufacturing equipment is connected to a manufacturing equipment 20 configured to manufacture the product on the plane. The manufacturing equipment 20 includes a coater 2 configured to coat the resist layer on the wafer, an exposure tool 3 configured to expose the resist layer to light, a heater 4 configured to bake the resist layer, and a developing tool 5 configured to develop the resist layer to form the resist pattern as the product on the wafer.

The CPU 300 includes an approximation module 121 configured to approximate a planar distribution of the plurality of sizes by an orthogonal polynomial. The orthogonal polynomial includes a plurality of terms. The plurality of terms correspond to a plurality of planar distribution components, respectively. The orthogonal polynomial is a function of coordinates on the plane. Each of the plurality of planar distribution components composing the planar distribution shows different behavior.

Further, the CPU 300 includes an association module 123 and an adjusting module 352. The association module 123 is configured to associate the plurality of terms with a plurality of equipment parameters of the manufacturing equipment 20 that manufactures the product. The adjusting module 352 is configured to adjust the plurality of equipment parameters to reduce the plurality of distribution components composing the planar distribution.

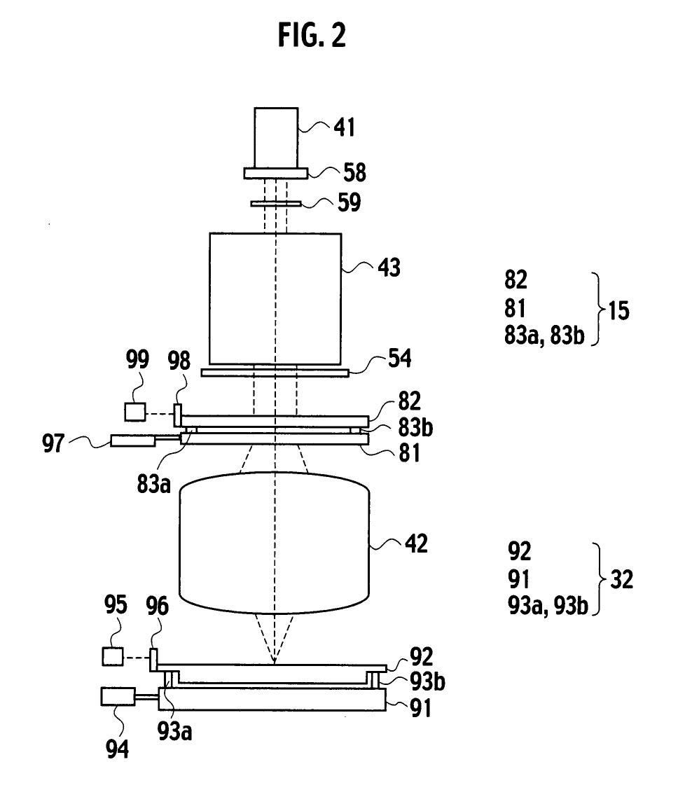

The coater 2 is configured to coat an anti reflective layer and the resist layer on the wafer. A spin coater can be used for the coater 2, for example. With reference next to FIG. 2, the exposure tool 3 includes a light source 41 emitting the light such as the ArF laser, an aperture diaphragm holder 58 disposed under the light source 41, a polarizer 59 polarizing the light emitted from the light source 41, an illuminator 43 condensing the light, a slit holder 54 disposed under the illuminator 43, a reticle stage 15 disposed beneath the slit holder 54, a projection optical system 42 disposed beneath the reticle stage 15, and a wafer stage 32 disposed beneath the projection optical system 42.

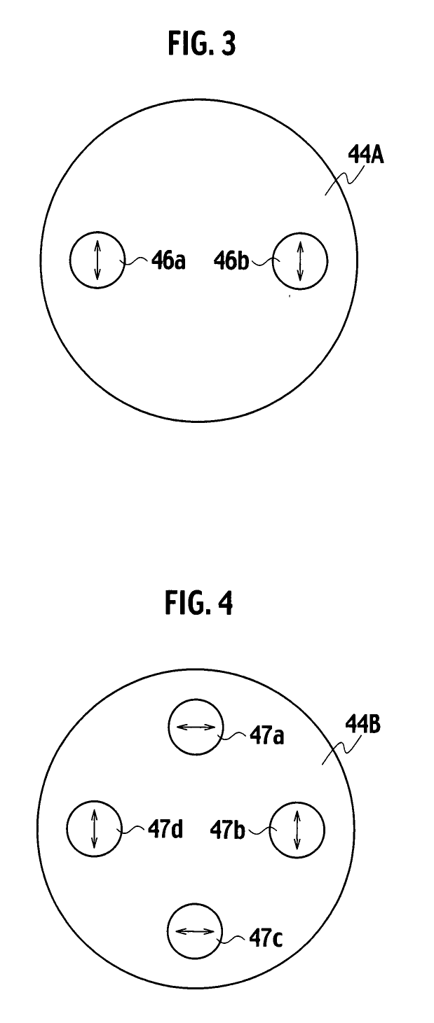

For example, the polarizer 59, shown in FIG. 3, includes a light shielding plate 44A and two circular polarizing filters 46a, 46b provided in the light shielding plate 44A. The polarization directions of lights passing through the polarizing filters 46a, 46b are parallel across the optical axis, as shown by arrows. Alternatively, the polarizer 59, shown in FIG. 4, includes a light shielding plate 44B and four circular polarizing filters 47a, 47b, 47c, 47d provided in the light shielding plate 44B, for example. The polarizing filters 47a-47d are oriented so that the light is azimuthally polarized, as shown by the arrows. The polarizer 59 provides the multipole illuminations such as the dipole or quadrupole illuminations.

A photomask is disposed on the reticle stage, shown in FIG. 2. The reticle stage 15 includes a reticle XY stage 81, shafts 83a, 83b provided on the reticle XY stage 81, and a reticle tilting stage 82 attached to the reticle XY stage 81 through the shafts 83a, 83b. The reticle stage 15 is attached to a reticle stage aligner 97. The reticle stage aligner 97 aligns the position of the reticle XY stage 81. Each of the shafts 83a, 83b extends from the reticle XY stage 81. Therefore, the position of the reticle tilting stage 82 is determined by the reticle XY stage 81. The tilt angle of the reticle tilting stage 82 is determined by the shafts 83a, 83b. Further, a reticle stage mirror 98 is attached to the edge of the reticle tilting stage 82. The position of the reticle tilting stage 82 is monitored by an interferometer 99 disposed opposite the reticle stage mirror 98.

The numerical aperture (NA) of the projection optical system 42 is 1.3, for example. The projection magnification of the projection optical system 42 is ¼, for example. The wafer coated with the resist layer is disposed on the wafer stage 32. A pattern delineated on the photomask is projected onto the resist layer. The wafer stage 32 includes a wafer XY stage 91, shafts 93a, 93b provided on the wafer XY stage 91, and a wafer tilting stage 92 attached to the wafer XY stage 91 through the shafts 93a, 93b. The wafer stage 32 is attached to a wafer stage aligner 94. The wafer stage aligner 94 aligns the position of the wafer XY stage 91. Each of the shafts 93a, 93b extends from the wafer XY stage 91. Therefore, the position of the wafer tilting stage 92 is determined by the wafer XY stage 91. The tilt angle of the wafer tilting stage 92 is determined by the shafts 93a, 93b. Further, a wafer stage mirror 96 is attached to the edge of the wafer tilting stage 92. The position of the wafer tilting stage 92 is monitored by an interferometer 95 disposed opposite the wafer stage mirror 96.

With reference to FIG. 1, the heater 4 is configured to perform a post exposure bake (PEB) for the resist layer on the wafer exposed to the light by the exposure tool 3. Baking conditions such as baking temperature and baking time of the heater 4 can be controlled. The developing tool 5 is configured to develop the resist layer. Developing conditions such as concentration of developing solution, temperature of the developing solution, and developing time in the developing tool 5 can be controlled.

The measurement equipment 332 defines x-y coordinate system on the wafer, for example. Further, the measurement equipment 332 measures the sizes of the portions of the product such as the resist pattern at each of a plurality of measurement coordinates on the wafer. When the equipment parameters of the coater 2, the exposure tool 3, the heater 4, and the developing tool 5 are not optimized, the sizes of the portions of the resist pattern on the wafer may vary.

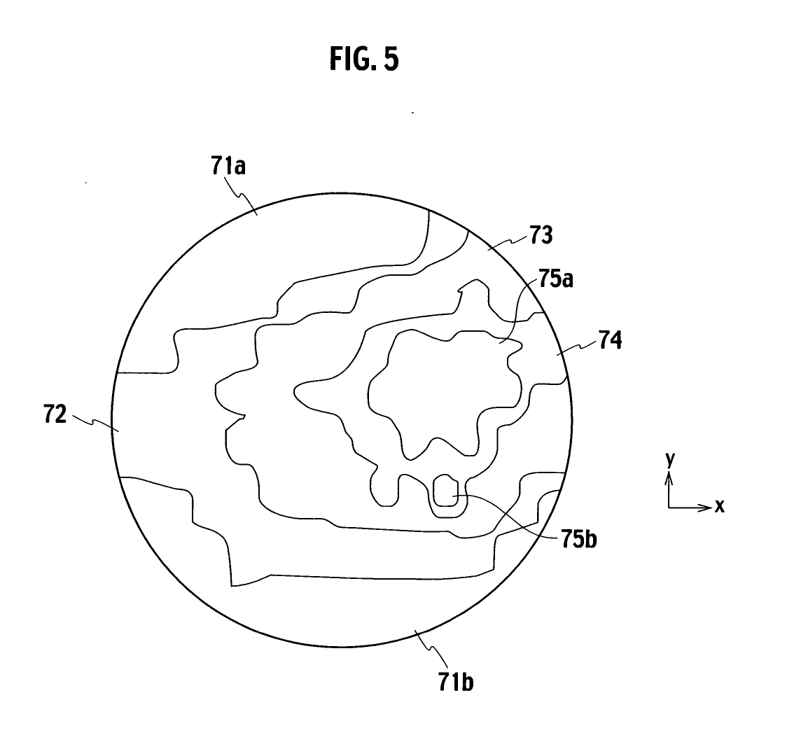

For example, even though the design value of the line width of the resist pattern is 65 nm, the line widths of the portions of the manufactured resist pattern vary from 61.7 nm to 62.7 nm on a first field 71a, 71b on the wafer, as shown in FIG. 5. The line widths of the portions of the manufactured resist pattern vary from 62.7 nm to 63.7 nm on a second field 72 on the wafer. The line widths of the manufactured resist pattern vary from 64.7 nm to 65.7 nm on a third field 73 on the wafer. The line widths of the manufactured resist pattern vary from 65.7 nm to 66.7 nm on a fourth field 74 on the wafer. The line widths of the manufactured resist pattern vary from 66.7 nm to 67.7 nm on a fifth field 75a, 75b on the wafer. An atomic force microscope (AFM) and a scanning electron microscope (SEM) can be used for the measurement equipment 332, shown in FIG. 1.

The approximation module 121 approximates the planar distribution of the sizes of the portions of the product on the wafer by the orthogonal polynomial such as Zernike polynomial. The Zernike polynomial is given by equation (1).

$$\begin{matrix}W ( r , Φ ) = {a}_{1} {Z}_{1} ( r , Φ ) + {a}_{2} {Z}_{2} ( r , Φ ) + {a}_{3} {Z}_{3} ( r , Φ ) + … \\ = {\sum }_{n = 1}^{m} {a}_{n} {Z}_{n} ( r , Φ )\end{matrix} \qquad ( 1 )$$

In the equation (1), “r” is a distance between an original point “O” of the x-y coordinate system defined on the wafer and the measurement coordinates where the size of the portion of the product is measured. “φ” is an angle between an x axis and a line connecting the original point “O” and the measurement coordinates. W (r, φ) is the size of the portion of the product at any measurement coordinates on the wafer. Also, the first to sixth terms in the Zernike polynomial are given by equations (2)-(7).
Z₁(r, φ)=1 (2)
Z₂(r, φ)=r cos φ (3)
Z₃(r, φ)=r sin φ (4)
Z₄(r, φ)=2r²−1 (5)
Z₅(r, φ)=r² cos 2φ (6)
Z₆(r, φ)=r² sin 2φ (7)

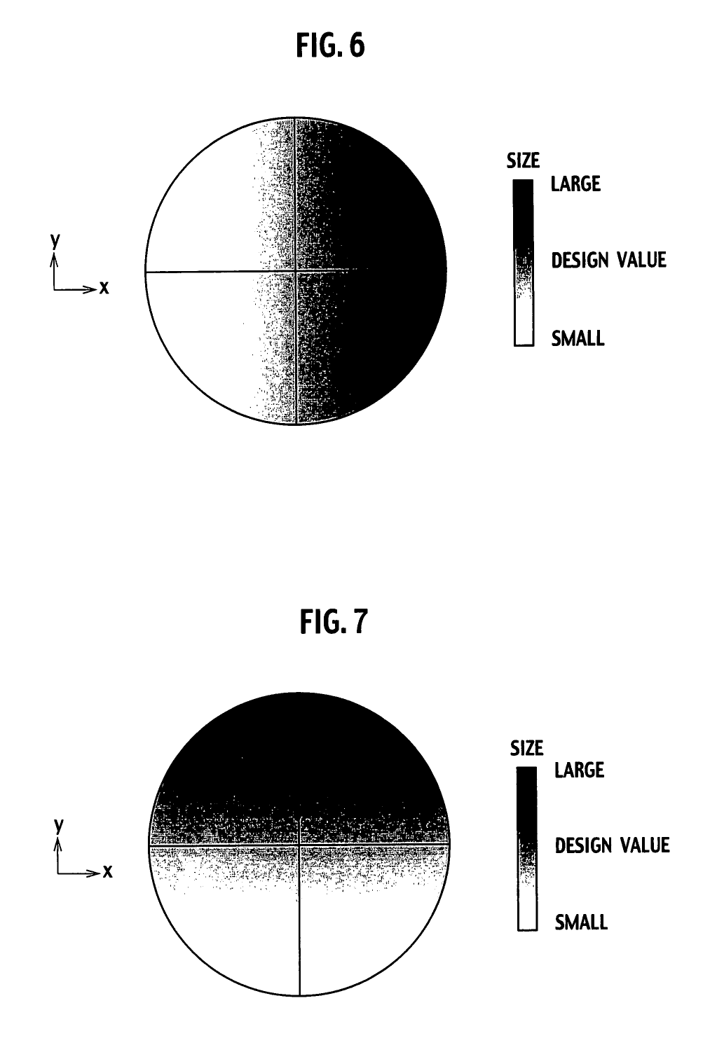

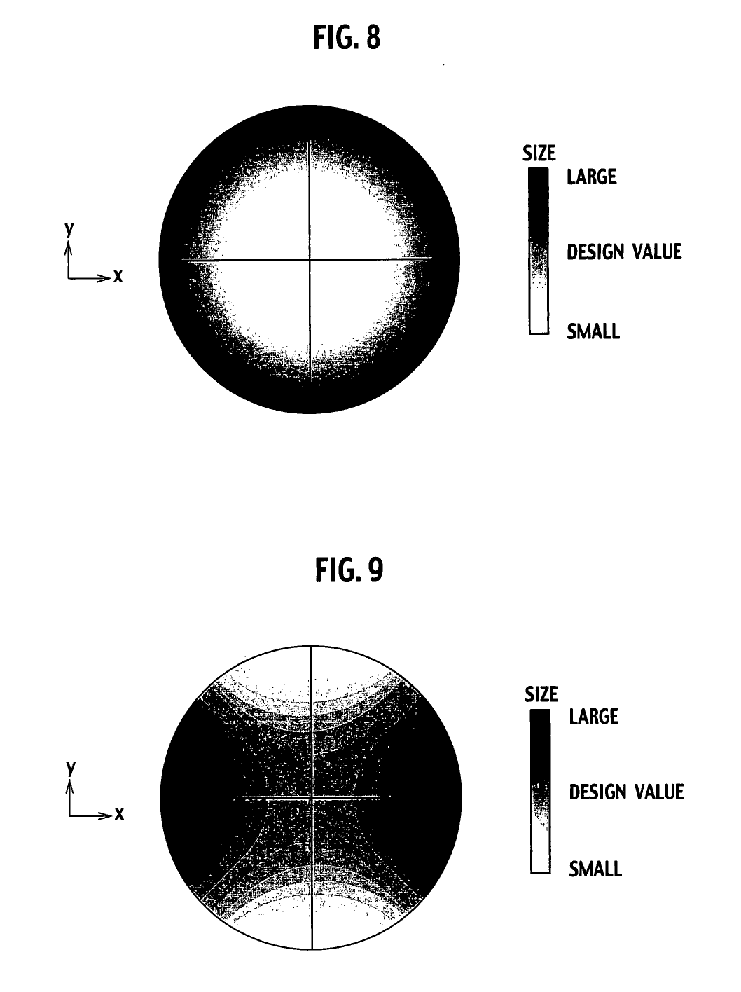

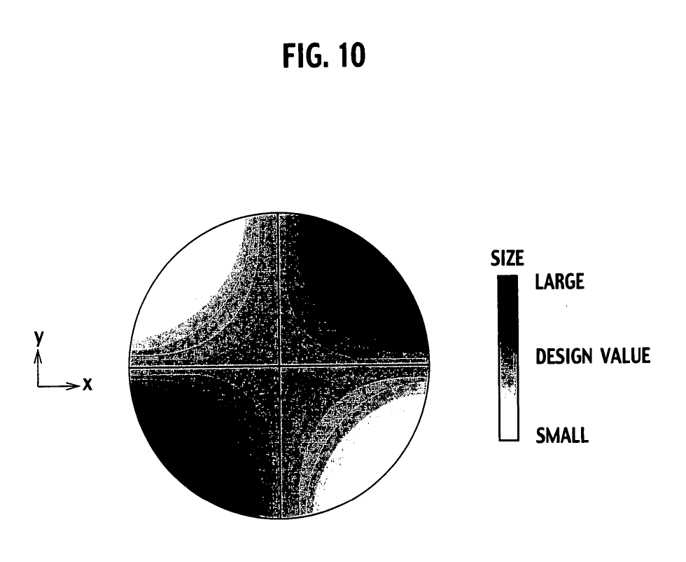

As given by the equation (2), the first term in the Zernike polynomial is a constant term. The second term, given by the equation (3) , shows the distribution component in x direction, as shown in FIG. 6. The distribution component in the x direction is contained in the planar distribution. The third term, given by the equation (4), shows the distribution component in y direction, as shown in FIG. 7. The distribution component in the y direction is contained in the planar distribution. The fourth term, given by the equation (5), shows the distribution component in concentric direction, as shown in FIG. 8. The distribution component in the concentric direction is contained in the planar distribution. The fifth term, given by the equation (6) , shows the distribution component in zero degrees direction and 90 degrees direction, as shown in FIG. 9. The distribution component in the zero degrees direction and the 90 degrees direction is contained in the planar distribution. The sixth term, given by the equation (7), shows the distribution component in −45 degrees direction and +45 degrees direction, as shown in FIG. 10. The distribution component in the −45 degrees direction and the +45 degrees direction is contained in the planar distribution.

For example, when the W(r₁, φ₁) that is the size of the portion of the product at the first measurement coordinates (r₁, φ₁) is 61 nm, the Zernike polynomial is given by equation (8).

$$61 = {a}_{1} + {a}_{2} {r}_{1} cos {ϕ}_{1} + {a}_{3} {r}_{1} sin {ϕ}_{1} + {a}_{4} ( 2 {r}_{1}^{2} - 1 ) + {a}_{5} {r}_{1}^{2} cos 2 {ϕ}_{1} + {a}_{6} {r}_{1}^{2} sin 2 {ϕ}_{1} \qquad ( 8 )$$

When the W(r₂, φ₂) that is the size of the portion of the product at the second measurement coordinates (r₂, φ₂) is 62 nm, the Zernike polynomial is given by equation (9).

$$62 = {a}_{1} + {a}_{2} {r}_{2} cos {ϕ}_{2} + {a}_{3} {r}_{2} sin {ϕ}_{2} + {a}_{4} ( 2 {r}_{2}^{2} - 1 ) + {a}_{5} {r}_{2}^{2} cos 2 {ϕ}_{2} + {a}_{6} {r}_{2}^{2} sin 2 {ϕ}_{2} \qquad ( 9 )$$

When the W(r₃, φ₃) that is the size of the portion of the product at the third measurement coordinates (r₃, φ₃) is 59 nm, the Zernike polynomial is given by equation (10).

$$59 = {a}_{1} + {a}_{2} {r}_{3} cos {ϕ}_{3} + {a}_{3} {r}_{3} sin {ϕ}_{3} + {a}_{4} ( 2 {r}_{3}^{3} - 1 ) + {a}_{5} {r}_{3}^{2} cos 2 {ϕ}_{3} + {a}_{6} {r}_{3}^{2} sin 2 {ϕ}_{3} \qquad ( 10 )$$

When the W(r₄, φ₄) that is the size of the portion of the product at the fourth measurement coordinates (r₄, φ₄) is 66 nm, the Zernike polynomial is given by equation (11).

$$66 = {a}_{1} + {a}_{2} {r}_{4} cos {ϕ}_{4} + {a}_{3} {r}_{4} sin {ϕ}_{2} + {a}_{4} ( 2 {r}_{4}^{2} - 1 ) + {a}_{5} {r}_{4}^{2} cos 2 {ϕ}_{4} + {a}_{6} {r}_{4}^{2} sin 2 {ϕ}_{4} \qquad ( 11 )$$

When the W(r₅, φ₅) that is the size of the portion of the product at the fifth measurement coordinates (r₅, φ₅) is 58 nm, the Zernike polynomial is given by equation (12).

$$58 = {a}_{1} + {a}_{2} {r}_{5} cos {ϕ}_{5} + {a}_{3} {r}_{5} sin {ϕ}_{5} + {a}_{4} ( 2 {r}_{5}^{4} - 1 ) + {a}_{5} {r}_{5}^{2} 2 {ϕ}_{5} + {a}_{6} {r}_{5}^{2} sin 2 {ϕ}_{5} \qquad ( 12 )$$

When the W(r₆, φ₆) that is the size of the portion of the product at the sixth measurement coordinates (r₆, φ₆) is 60 nm, the Zernike polynomial is given by equation (13).

$$60 = {a}_{1} + {a}_{2} {r}_{6} cos {ϕ}_{6} + {a}_{3} {r}_{6} sin {ϕ}_{6} + {a}_{4} ( 2 {r}_{6}^{2} - 1 ) + {a}_{5} {r}_{6}^{2} cos 2 {ϕ}_{6} + {a}_{6} {r}_{6}^{2} sin 2 {ϕ}_{6} \qquad ( 13 )$$

The approximation module 121 calculates the expansion coefficients “a₁”, “a₂”, “a₃”, “a₄”, “a₅”, “a₆” in the first to sixth terms of the Zernike polynomial by solving the simultaneous equations given by the equations (8)-(13). A second expansion coefficient “a₂” that is the expansion coefficient in the second term shows the distribution component in the x direction, shown in FIG. 6. When the second expansion coefficient “a₂” is large, the size of the portion of the product continuously and drastically changes in the x direction. In contrast, when the second expansion coefficient “a₂” is small, the size of the portion of the product continuously and slightly changes in the x direction.

A third expansion coefficient “a₃” that is the expansion coefficient in the third term shows the distribution component in the y direction, shown in FIG. 7. When the third expansion coefficient “a₃” is large, the size of the portion of the product continuously and drastically changes in the y direction. In contrast, when the third expansion coefficient “a₃” is small, the size of the portion of the product continuously and slightly changes in the y direction.

A fourth expansion coefficient “a₄” that is the expansion coefficient in the fourth term shows the distribution component in the concentric direction, shown in FIG. 8. When the fourth expansion coefficient “a₄” is large, the size of the portion of the product continuously and drastically changes in the concentric direction. In contrast, when the fourth expansion coefficient “a₄” is small, the size of the portion of the product continuously and slightly changes in the concentric direction.

A fifth expansion coefficient “a₅” that is the expansion coefficient in the fifth term shows the distribution component in the zero degrees direction and the 90 degrees direction, shown in FIG. 9. When the fifth expansion coefficient “a₅” is large, the size of the portion of the product continuously and drastically changes in the zero degrees direction and the 90 degrees direction. In contrast, when the fifth expansion coefficient “a₅” is small, the size of the portion of the product continuously and slightly changes in the zero degrees direction and the 90 degrees direction.

A sixth expansion coefficient “a₆” that is the expansion coefficient in the sixth term shows the distribution component in the −45 degrees direction and the +45 degrees direction, shown in FIG. 10. When the sixth expansion coefficient “a₆” is large, the size of the portion of the product continuously and drastically changes in the −45 degrees direction and the +45 degrees direction. In contrast, when the sixth expansion coefficient “a₆” is small, the size of the portion of the product continuously and slightly changes in the −45 degrees direction and the +45 degrees direction.

Even if the sizes of the portions of the resist pattern on the wafer show the random and planar distribution, as shown in FIG. 5, the random and planar distribution can be decomposed into the plurality of distribution components that show the specific behaviors respectively, by approximating the planar distribution by the Zernike polynomial.

With reference again to FIG. 1, a term selector 21 is configured to select the terms to be contained in the Zernike polynomial approximated by the approximation module 121. In theory, the Zernike polynomial infinitely contains the plurality of terms. However, depending on the processing power of the CPU 300, the number of the terms to be contained in the Zernike polynomial is limited. Therefore, the term selector 21 selects the terms to be contained in the Zernike polynomial, depending on the processing power of the CPU 300 and the instruction from an operator.

A judging module 122 is configured to judge whether each value of the second expansion coefficient “a₂”, the third expansion coefficient “a₃”, the fourth expansion coefficient “a₄”, the fifth expansion coefficient “a₅”, and the sixth expansion coefficient “a₆” is within an allowable range or not. As described above, the values of the second to sixth expansion coefficients “a₂”-“a₆” show the intensities of the distribution components corresponding to the second to sixth terms, respectively. Therefore, when the second to sixth expansion coefficients “a₂”-“a₆” have the large values to bring an error of the semiconductor device to be manufactured, the judging module 122 judges that each of the second to sixth expansion coefficients “a₂”-“a₆” is outside the allowable range.

The association module 123 ranks the plurality of terms of the Zernike polynomial in descending order, based on each value of the second to sixth expansion coefficients “a₂”-“a₆” that are outside the allowable range. Also, the association module 123 ranks the plurality of equipment parameters of the coater 2, the exposure tool 3, the heater 4, and the developing tool 5 in descending order, based on widths of adjustable ranges of the equipment parameters.

Here, the equipment parameters of the spin coater 2 include adjustable rotational acceleration, rotational velocity, rotation time, an angle of the fixed wafer, an amount of the resist solution, and sucking force to hold the wafer, for example. The equipment parameters of the exposure tool 3 include the adjustable illumination condition, the polarization direction of the light, the coherence factor a, the numerical aperture (NA), a depth of focus, a focal length, an aberration, and the angle of the tilted wafer stage 32, for example. The equipment parameters of the heater 4 include adjustable temperature, baking position, humidity, baking velocity, baking time, and wind velocity, for example. The equipment parameters of the developing tool 5 include adjustable amount of the developing solution, the temperature, spray condition of the developing solution, and the developing time.

Further, the association module 123 associates the first ranked term with the highly ranked equipment parameter that can adjust the distribution component corresponding to the first ranked term. When the first ranked terms are the second term and the third term, for example, the second term and the third term are associated with the highly ranked equipment parameters that can adjust the distribution components in the x direction and the y direction, such as the angle of the fixed wafer in the cater 2, the angle of the tilted wafer stage 32 in the exposure tool 3, the baking position on the wafer in the heater 4, and the spray condition of the developing solution in the developing tool 5.

Also, the association module 123 associates the second ranked term with the highly ranked equipment parameter that can adjust the distribution component corresponding to the second ranked term. It should be noted that the equipment parameters already associated with the first ranked term are not associated with the second ranked term. When the second ranked term is the fourth term, for example, the fourth term is associated with the highly ranked equipment parameters that can adjust the distribution component in the concentric direction, such as the rotational acceleration of the spin coater 2, the aberration of the projection optical system 42 in the exposure tool 3, the baking position on the wafer in the heater 4, and the spray condition of the developing solution.

Also, the association module 123 associates the third ranked term with the highly ranked equipment parameter that can adjust the distribution component corresponding to the third ranked term. It should be noted that the equipment parameters already associated with the first and second ranked terms are not associated with the third ranked term. When the third ranked term is the fifth term, for example, the fifth term is associated with the highly ranked equipment parameters that can adjust the distribution component in the zero degrees direction and the 90 degrees direction, such as the sucking force to hold the wafer in the coater 2, the polarization direction by the polarizing filters 47a, 47c of the polarizer 59, shown in FIG. 4, in the exposure tool 3, and the baking position on the wafer in the heater 4, shown in FIG. 1.

Also, the association module 123 associates the fourth ranked term with the highly ranked equipment parameter that can adjust the distribution component corresponding to the fourth ranked term. It should be noted that the equipment parameters already associated with the first, second, and third ranked terms are not associated with the fourth ranked term. When the fourth ranked term is the sixth term, for example, the sixth term is associated with the highly ranked equipment parameters that can adjust the distribution component in the −45 degrees direction and the +45 degrees direction, such as the sucking force to hold the wafer in the coater 2, the polarization direction by the polarizing filters 47a, 47c of the polarizer 59, shown in FIG. 4, in the exposure tool 3, and the baking position on the wafer in the heater 4, shown in FIG. 1.

The adjusting module 352 includes a coater controller 252, an exposure tool controller 253, a heater controller 254, and a developer controller 255. The coater controller 252 adjusts the equipment parameters of the coater 2 to reduce the distribution components corresponding to the terms in the Zernike polynomial that are associated with the equipment parameters of the coater 2 by the association module 123. When the second and third terms showing the distribution components in the x direction and the y direction are associated with the angle of the fixed wafer in the coater 2, for example, the coater controller 252 adjusts the angle of the fixed wafer in the coater 2 to reduce the distribution components in the x direction and the y direction. The angle of the fixed wafer is adjusted, depending on the values of the second expansion coefficient and the third expansion coefficient. When the fourth term showing the distribution component in the concentric direction is associated with the rotational acceleration of the coater 2, for example, the coater controller 252 adjusts and increases the rotational acceleration of the spin coater 2 to reduce the distribution component in the concentric direction. How the coater controller 252 accelerates the rotational acceleration depends on the value of the fourth expansion coefficient.

When the fifth term showing the distribution component in the zero degrees direction and 90 degrees direction is associated with the vacuum sucking force to hold the wafer in the coater 2, for example, the coater controller 252 adjusts the vacuum sucking force to hold the wafer in the coater 2 to reduce the distribution components in the zero degrees direction and the 90 degrees direction. The vacuum sucking force to hold the wafer in the coater 2 is adjusted, depending on the value of the fourth expansion coefficient in the fourth term. When the sixth term showing the distribution component in the −45 degrees direction and +45 degrees direction is associated with the vacuum sucking force to hold the wafer in the coater 2, the coater controller 252 adjusts the vacuum sucking force to hold the wafer in the coater 2 to reduce the distribution component in the −45 degrees direction and the +45 degrees direction.

The exposure tool controller 253 adjusts the equipment parameters of the exposure tool 3 to reduce the distribution components corresponding to the terms in the Zernike polynomial. When the second term showing the distribution component in the x direction or the third term showing the distribution component in the y direction is associated with the angle of the tilted wafer stage 32 in the exposure tool 3, for example, the exposure tool controller 253 adjusts the angle of the tilted wafer stage 32 in the exposure tool 3 to reduce the distribution component in the x direction or the y direction. The exposure tool controller 253 adjusts the angle of the tilted wafer stage 32, depending on the value of the second expansion coefficient or the value of the third expansion coefficient. Alternatively, when the second or third term is associated with the polarization direction of the light in the exposure tool 3, the exposure tool controller 253 adjusts and rotates the polarization direction of the light passing through the polarizing filter 46a of the polarizer 59, shown in FIG. 3, by 90 degrees to reduce the distribution component in the x direction or the y direction.

When the fourth term showing the distribution component in the concentric direction is associated with the aberration of the exposure tool 3, shown in FIG. 1, the exposure tool controller 253 adjusts the aberration of the projection optical system 42 in the exposure tool 3 to reduce the distribution component in the concentric direction. The aberration is adjusted, depending on the value of the fourth expansion coefficient.

When the fifth term showing the distribution component in the zero degrees direction and the 90 degrees direction is associated with the polarization direction of the light in the exposure tool 3, the exposure tool controller 253 adjusts the polarization direction of the light passing through the polarizing filters 47a, 47c of the polarizer 59, shown in FIG. 4, in the exposure tool 3 to reduce the distribution component in the zero degrees direction and the 90 degrees direction. The polarization direction is adjusted, depending on the value of the fifth expansion coefficient.

When the sixth term showing the distribution component in the −45 degrees direction and the +45 degrees direction is associated with the polarization direction of the light in the exposure tool 3, the exposure tool controller 253 adjusts the polarization direction of the light passing through the polarizing filters 47a, 47c of the polarizer 59, shown in FIG. 4, in the exposure tool 3 to reduce the distribution component in the −45 degrees direction and the +45 degrees direction. The polarization direction is adjusted, depending on the value of the sixth expansion coefficient.

The heater controller 254, shown in FIG. 1, adjusts the equipment parameters of the heater 4 to reduce the distribution components corresponding to the terms in the Zernike polynomial that are associated with the equipment parameters of the heater 4 by the association module 123. When the sixth term showing the distribution component in the −45 degrees direction and the +45 degrees direction is associated with the baking position and the baking temperature in the heater 4, for example, the heater controller 254 adjusts the baking position and the baking temperature in the heater 4 to reduce the distribution component in the −45 degrees direction and the +45 degrees direction. The baking position and the baking temperature are adjusted, depending on the value of the sixth expansion coefficient.

The developer controller 255 adjusts the equipment parameters of the developing tool 5 to reduce the distribution components corresponding to the terms in the Zernike polynomial that are associated with the equipment parameters of the developing tool 5 by the association module 123. When the second term showing the distribution components in the x direction is associated with the spray condition of the developing solution in the developing tool 5, for example, the developer controller 255 adjusts the spray condition of the developing solution in the developing tool 5 to reduce the distribution component in the x direction. The spray condition of the developing solution is adjusted, depending on the value of the second expansion coefficient.

A data memory 335 is connected to the CPU 300. The data memory 335 includes a tool information memory module 336, a size memory module 338, a selected term memory module 339, an approximation formula memory module 340, a coefficient memory module 341, and an association memory module 342. The tool information memory module 336 stores the adjustable ranges of the equipment parameters of the coater 2, the exposure tool 3, the heater 4, and the developing tool 5. The size memory module 338 stores each size of the portions of the resist pattern measured by the measurement equipment 332. The selected term memory module 339 stores the plurality of terms in the Zernike polynomial selected by the term selector 21. The approximation formula memory module 340 stores the Zernike polynomial approximated by the approximation module 121. The coefficient memory module 341 stores the plurality of terms in the Zernike polynomial containing the plurality of expansion coefficients judged as outside the allowable range by the judging module 122. The association memory module 342 stores the terms associated with the equipment parameters by the association module 123.

An input unit 312, an output unit 313, a program memory 330, and a temporary memory 331 are also connected to the CPU 300. A keyboard and a mouse may be used for the input unit 312. A printer and display devices such as a liquid crystal display (LCD) and a cathode ray tube (CRT) display can be used for the output unit 313, for example. The program memory 330 stores a program instructing the CPU 300 to transfer data with apparatuses connected to the CPU 300. The temporary memory 331 stores temporary data calculated during operation by the CPU 300. Computer readable mediums such as semiconductor memories, magnetic memories, optical discs, and magneto optical discs can be used for the program memory 330 and the temporary memory 331, for example.

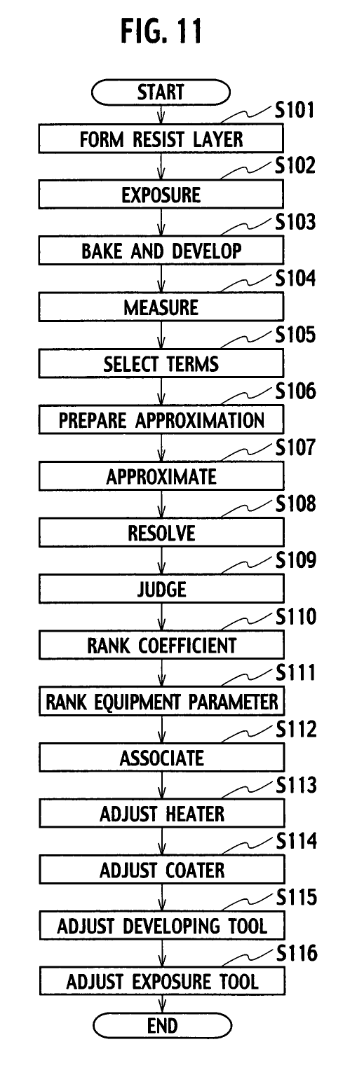

With reference next to FIG. 11, a method for adjusting the manufacturing equipment, according to the first embodiment of the present invention, is described. It should be noted that operation results by the CPU 300, shown in FIG. 1, are successively stored in the temporary memory 331.

In step S101, the photoresist is coated on the wafer by the spin coater 2 to form the resist layer on the wafer. Thereafter, the resist layer is preliminarily baked by the heater 4. In step S102, the wafer is disposed on the wafer stage 32 in the exposure tool 3, shown in FIG. 2. Then, the light is emitted from the light source 41. Accordingly, the image of the mask pattern on the photomask disposed on the reticle stage 15 is projected onto the resist layer. Further, the step and scan are repeated to project the plurality of images of the mask pattern onto the resist layer.

In step S103, the PEB is performed for the resist layer by the heater 4, shown in FIG. 1. Then, the resist layer is developed by the developing tool 5 to form the resist pattern on the wafer. The resist pattern corresponds to the image of the mask pattern. In step S104, the plurality of sizes of the line widths of the portions of the resist pattern are measured by the measurement equipment 332. The plurality of measured sizes and the plurality of corresponding measured coordinates are stored in the size memory module 338, shown in FIG. 1.

In step S105, the term selector 21 selects the plurality of terms to be contained in the Zernike polynomial that is given by the equation (1) and is to approximate the planar distribution of the plurality of sizes. The term selector 21 stores the information about the plurality of selected terms in the selected term memory module 339. For example, the first, second, third, fourth, fifth, and sixth terms in the Zernike polynomial are selected by the terms selector 21.

In step S106, the approximation module 121 fetches the plurality of sizes and the plurality of corresponding measurement coordinates from the size memory module 338. Also, the approximation module 121 fetches the information about the plurality of terms selected by the term selector from the selected term memory module 339. In step S107, the approximation module 121 approximates the relationship between the plurality of sizes and the plurality of measurement coordinates by the Zernike polynomial having the selected first to sixth terms. The approximation module 121 stores the calculated Zernike polynomial in the approximation formula memory module 340.

In step S108, the judging module 122 fetches the second term in the Zernike polynomial as the distribution component in the x direction, shown in FIG. 6, from the approximation formula memory module 340. Also, the judging module 122 fetches the third term as the distribution component in the y direction, shown in FIG. 7, the fourth term as the distribution component in the concentric direction, shown in FIG. 8, the fifth term as the distribution component in the zero degrees direction and the 90 degrees direction, shown in FIG. 9, and the sixth term as the distribution component in the −45 degrees direction and the +45 degrees direction, shown in FIG. 10, from the approximation formula memory module 340.

In step S109, the judging module 122, shown in FIG. 1, judges whether each of the second to sixth expansion coefficients “a₂”-“a₆” is within the allowable range or not. The second to sixth expansion coefficients “a₂”-“a₆” show the intensities of the distribution components corresponding to the second to sixth terms, respectively. When the term has the expansion coefficient outside the allowable range, the intensity of the corresponding distribution component is high. Therefore, the factor of the corresponding distribution component should be corrected. The judging module 122 stores the term having the expansion coefficient outside the allowable range in the coefficient memory module 341. For example, the second to fifth expansion coefficients “a₂”-“a₅” are outside the allowable range.

In step S110, the association module 123 fetches the terms having the second to fifth expansion coefficients “a₂”-“a₅” outside the allowable range from the coefficient memory module 341. Next, the association module 123 ranks the plurality of terms in descending order, based on the plurality of values of the second to fifth expansion coefficients “a₂”-“a₅”. For example, the plurality of terms are sorted according to the rank, the fifth term, the fourth term, the second term, and the third term.

In step S111, the association module 123 fetches the adjustable ranges of the equipment parameters of the coater 2, the exposure tool 3, the heater 4, and the developing tool 5 from the tool information memory module 336. Thereafter, the association module 123 ranks the equipment parameters of the coater 2, the exposure tool 3, the heater 4, and the developing tool 5 in descending order, based on the widths of the adjustable ranges of the equipment parameters. For example, the equipment parameters are sorted according to the rank, the baking position on the wafer in the heater 4, the rotational acceleration of the coater 2, the spray condition of the developing solution in the developing tool 5, and the angle of the tilted wafer stage 32 in the exposure tool 3.

In step S112, the association module 123 associates the fifth term having the first ranked expansion coefficient with the baking position in the heater 4 having the first ranked adjustable range. The association module 123 stores the fifth term associated with the baking position in the heater 4 in the association memory module 342. Next, the association module 123 associates the fourth term having the second ranked expansion coefficient with the rotational acceleration of the coater 2 having the second ranked adjustable range. The association module 123 stores the fourth term associated with the rotational acceleration of the coater 2 in the association memory module 342. Next, the association module 123 associates the second term having the third ranked expansion coefficient with the spray condition in the developing tool 5 having the third ranked adjustable range. The association module 123 stores the second term associated with the spray condition in the developing tool 5 in the association memory module 342. Next, the association module 123 associates the third term having the fourth ranked expansion coefficient with the angle of the tilted wafer stage 32 in the exposure tool 3 having the fourth ranked adjustable range. The association module 123 stores the third term associated with the angle of the tilted wafer stage 32 in the exposure tool 3 in the association memory module 342.

In step S113, the heater controller 254 fetches the fifth term associated with the equipment parameters of the heater 4 from the association memory module 342. In the case where the fifth expansion coefficient “a₅” in the fifth term is large, the intensity of the distribution component in the zero degrees direction and the 90 degrees direction, shown in FIG. 9, is high. Therefore, the heater controller 254, shown in FIG. 1, adjusts the baking position on the wafer in the heater 4 to reduce the intensity of the distribution component in the zero degrees direction and the 90 degrees direction.

In step S114, the coater controller 252 fetches the fourth term associated with the equipment parameters of the coater 2 from the association memory module 342. In the case where the fourth expansion coefficient “a₄” in the fourth term is large, the intensity of the distribution component in the concentric direction, shown in FIG. 8, is high. Therefore, the coater controller 252, shown in FIG. 1, adjusts the spin coating condition such as the rotational acceleration of the spin coater 2 to reduce the intensity of the distribution component in the concentric direction.

In step S115, the developer controller 255 fetches the second term associated with the equipment parameters of the developing tool 5 from the association memory module 342. In the case where the second expansion coefficient “a₂” in the second term is large, the intensity of the distribution component in the x direction, shown in FIG. 6, is high. Therefore, the developer controller 255, shown in FIG. 1, adjusts the spray condition of the developing solution on the wafer in the developing tool 5 to reduce the intensity of the distribution component in the x direction.

In step S116, the exposure tool controller 253 fetches the third term associated with the equipment parameters of the exposure tool 3 from the association memory module 342. In the case where the third expansion coefficient “a₃” in the third term is large, the intensity of the distribution component in the y direction, shown in FIG. 7, is high. Therefore, the exposure tool controller 253, shown in FIG. 1, adjusts the angle of the tilted wafer stage 32 in the exposure tool 3, shown in FIG. 2, to reduce the intensity of the distribution component in the y direction and the method for adjusting the manufacturing equipment, according to the first embodiment, is completed.

As described above, the system and method for adjusting the manufacturing equipment, according to the first embodiment, decompose the planar distribution of the plurality of sizes of the portions of the product into the plurality of distribution components. Then, the equipment parameters of the manufacturing equipment 20 are adjusted to reduce the plurality of distribution components. Therefore, by using the manufacturing equipment 20 of which the equipment parameters are adjusted, it is possible to unify the planar distribution of the plurality of sizes of the portions of the resist pattern. Consequently, uniform resist pattern is manufactured. Also, it is possible to manufacture the precise semiconductor device by using the uniform resist pattern.

### SECOND EMBODIMENT

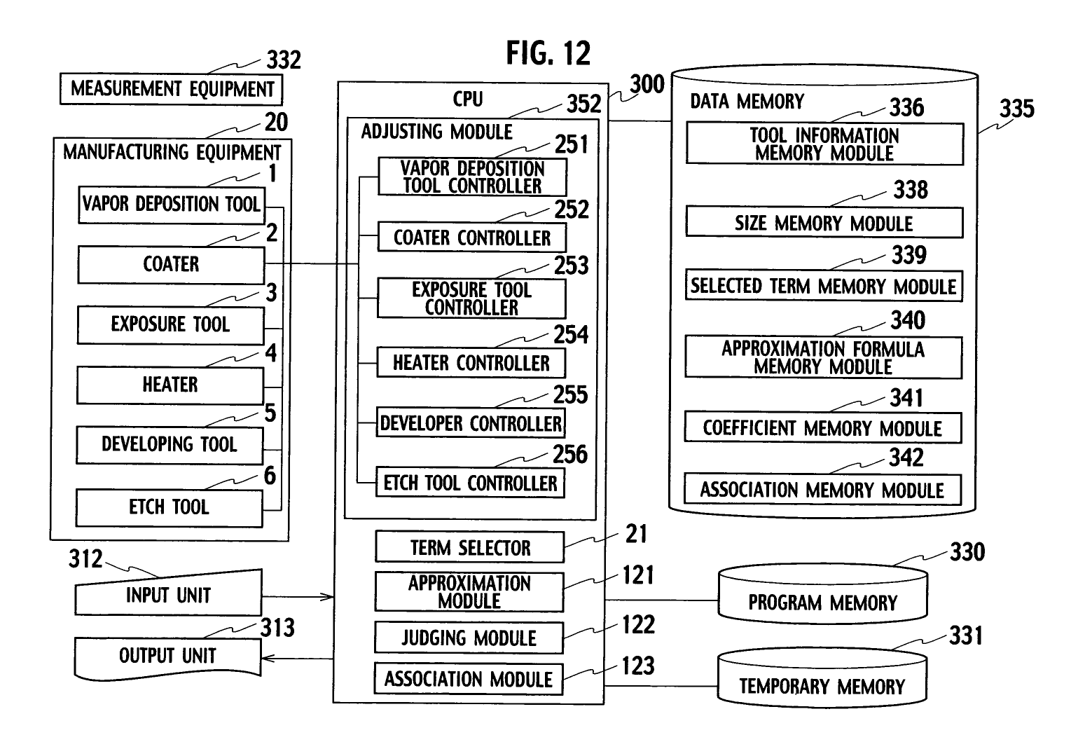

With reference to FIG. 12, the manufacturing equipment 20 connected to the CPU 300, according to the second embodiment, further includes a vapor deposition tool 1 and an etch tool 6. The vapor deposition tool 1 is configured to deposit the insulating layer on the wafer. The equipment parameters of the vapor deposition tool 1 include concentration of deposition materials, deposition time, deposition temperature, a shape of a deposition material blast nozzle, and a positional relationship between the blast nozzle and the wafer, for example. A chemical vapor deposition (CVD) tool can be used for the vapor deposition tool 1, for example.

The etch tool 6 is configured to selectively remove the insulating layer by using the resist pattern formed on the insulating layer by the coater 2, the exposure tool 3, the heater 4, and the developing tool 5 as an etchant mask. The equipment parameters of the etch tool 6 include concentration of etchant gas, etching time, etching temperature, a shape of etchant gas blast nozzle, a positional relationship between the blast nozzle and the wafer, for example.

In the second embodiment, the measurement equipment 332 measures a plurality depths of via holes in the insulating layer formed by the manufacturing equipment 20 as the plurality of sizes of the portions of the product, respectively. The association module 123 associates the equipment parameters of the vapor deposition tool 1 and the etch tool 6 with the terms in the Zernike polynomial.

The adjusting module 352, according to the second embodiment, further includes a vapor deposition tool controller 251 and an etch tool controller 256. The vapor deposition tool controller 251 adjusts the equipment parameters of the vapor deposition tool 1 to reduce the distribution component corresponding to the term in the Zernike polynomial associated with the equipment parameters of the vapor deposition tool 1 by the association module 123. When the second or third term showing the distribution component in the x direction or the y direction is associated with the angle between the wafer and the blast nozzle in the vapor deposition tool 1, for example, the vapor deposition tool controller 251 adjusts the angle between the wafer and the blast nozzle in the vapor deposition tool 1 to reduce the distribution component in the x direction or the y direction. When the fourth term showing the distribution component in the concentric direction is associated with the shape of the blast nozzle in the vapor deposition tool 1, for example, the vapor deposition tool controller 251 adjusts the shape of the blast nozzle in the vapor deposition tool 1 to reduce the distribution component in the concentric direction. When the fifth term showing the distribution component in the zero degrees direction and the 90 degrees direction is associated with the shape of the blast nozzle in the vapor deposition tool 1 or the heating position on the wafer, the vapor deposition tool controller 251 adjusts the shape of the blast nozzle in the vapor deposition tool 1 or the heating position on the wafer to reduce the distribution component in the zero degrees direction and the 90 degrees direction. When the sixth term showing the distribution component in the −45 degrees direction and the +45 degrees direction is associated with the shape of the blast nozzle in the vapor deposition tool 1 or the heating position on the wafer, for example, the vapor deposition tool controller 251 adjusts the shape of the blast nozzle in the vapor deposition tool 1 or the heating position on the wafer to reduce the distribution component in the −45 degrees direction and the +45 degrees direction.

The etch tool controller 256 adjusts the equipment parameters of the etch tool 6 to reduce the distribution components corresponding to the terms in the Zernike polynomial associated with the equipment parameters of the etch tool 6 by the association module 123. When the second or third term showing the distribution component in the x direction or the y direction is associated with the angle between the blast nozzle and the wafer in the etch tool 6, for example, the etch tool controller 256 adjusts the angle between the blast nozzle and the wafer in the etch tool 6 to reduce the distribution component in the x direction or the y direction. When the fourth term showing the distribution component in the concentric direction is associated with the shape of the blast nozzle in the etch tool 6, for example, the etch tool controller 256 adjusts the shape of the blast nozzle in the etch tool 6 to reduce the distribution component in the concentric direction. When the fifth term showing the distribution component in the zero degrees direction and the 90 degrees direction is associated with the shape of the blast nozzle or the heating position on the wafer in the etch tool 6, for example, the etch tool controller 256 adjusts the shape of the blast nozzle or the heating position on the wafer in the etch tool 6 to reduce the distribution component in the zero degrees direction and the 90 degrees direction. When the sixth term showing the distribution component in the −45 degrees direction and the +45 degrees direction is associated with the shape of the blast nozzle or the heating position on the wafer in the etch tool 6, for example, the etch tool controller 256 adjusts the shape of the blast nozzle or the heating position on the wafer in the etch tool 6 to reduce the distribution component in the −45 degrees direction and the +45 degrees direction.

The tool information memory module 336, according to the second embodiment, further stores the adjustable range of the equipment parameters of the vapor deposition tool 1 and the etch tool 6. Other components of the system for adjusting the manufacturing equipment, according to the second embodiment, are similar to the system shown in FIG. 1. Therefore, the detail explanation about the other components is eliminated.

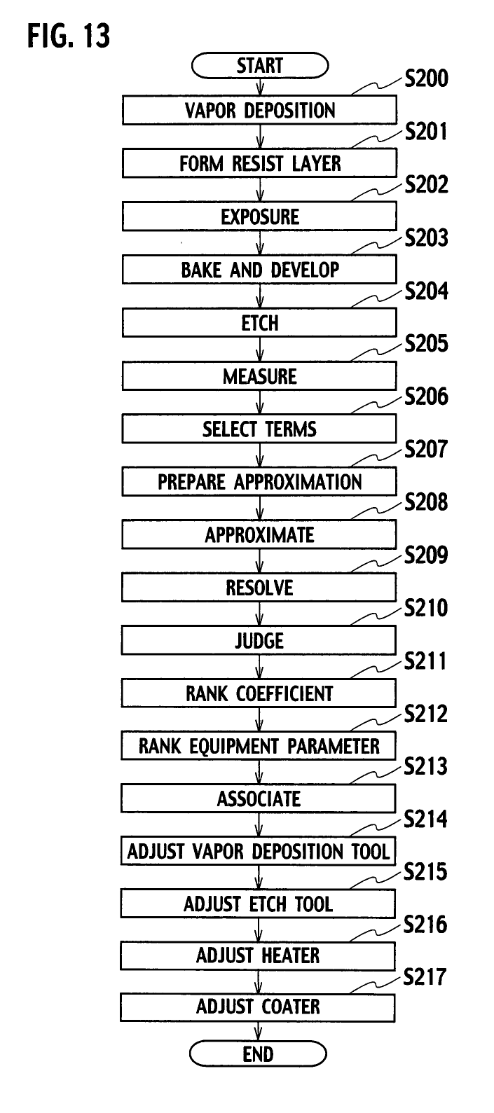

With reference next to FIG. 13, the method for adjusting the manufacturing equipment, according to the second embodiment of the present invention, is described.

In step S200, the vapor deposition tool 1, shown in FIG. 12, deposits the insulating layer on the wafer. In step S201, the photoresist is coated on the insulating layer by using the coater 2 to form the resist layer on the insulating layer. Next, step S202 and step S203 are carried out similar to step S102 and step S103 of FIG. 11. In step S204 of FIG. 13, the etch tool 6, shown in FIG. 12, selectively removes the insulating layer by using the resist pattern on the insulating layer as the etchant mask to form the plurality of via holes in the insulating layer.

In step S205, the measurement equipment 332 measures the plurality of depths of the via holes as the sizes of the portions of the product, respectively. The measurement equipment 332 stores the measured sizes and corresponding measurement coordinates in the size memory module 338, shown in FIG. 12. Thereafter, step S206 to step S211 are carried out similar to step S105 to step S110 of FIG. 11.

In step S212, the association module 123 fetches the adjustable ranges of the equipment parameters of the vapor deposition tool 1, the coater 2, the exposure tool 3, the heater 4, the developing tool 5, and the etch tool 6 from the tool information memory module 336. Thereafter, the association module 123 ranks the vapor deposition tool 1, the coater 2, the exposure tool 3, the heater 4, the developing tool 5, and the etch tool 6 in descending order, based on the widths of the adjustable ranges of the equipment parameters. For example, the plurality of equipment parameters are sorted according to the rank, the vapor deposition tool 1, the etch tool 6, the heater 4, the coater 2, the developing tool 5, and the exposure tool 3.

In step S213, the association module 123 associates the fifth term having the first ranked expansion coefficient with the vapor deposition tool 1 having the first ranked adjustable range of the equipment parameter. The association module 123 stores the fifth term associated with the vapor deposition tool 1 in the association memory module 342. Next, the association module 123 associates the fourth term having the second ranked expansion coefficient with the etch tool 6 having the second ranked adjustable range of the equipment parameter. The association module 123 stores the fourth term associated with the etch tool 6 in the association memory module 342. Next, the association module 123 associates the second term having the third ranked expansion coefficient with the heater 4 having the third ranked adjustable range of the equipment parameter. The association module 123 stores the second term associated with the heater 4 in the association memory module 342. Next, the association module 123 associates the third term having the fourth ranked expansion coefficient with the coater 2 having the fourth ranked adjustable range of the equipment parameters. The association module 123 stores the third term associated with the coater 2 in the association memory module 342.

In step S214, the vapor deposition tool controller 251 fetches the fifth term associated with the equipment parameters of the vapor deposition tool 1 from the association memory module 342. Thereafter, the vapor deposition tool controller 251 adjusts the shape of the blast nozzle or the heating position in the vapor deposition tool 1 to reduce the distribution component in the zero degrees direction and the 90 degrees direction.

In step S215, the etch tool controller 256 fetches the fourth term associated with the equipment parameters of the etch tool 6 from the association memory module 342. Thereafter, the etch tool controller 256 adjust the shape of the blast nozzle in the etch tool 6 to reduce the intensity of the distribution component in the concentric direction.

In step S216, the heater controller 254 fetches the second term associated with the equipment parameters of the heater 4 from the association memory module 342. Thereafter, the developer controller 255 adjusts the heating position on the wafer in the heater 4 to reduce the intensity of the distribution component in the x direction.

In step S217, the coater controller 252 fetches the third parameter associated with the equipment parameters of the coater 2 from the association memory module 342. Thereafter, the coater controller 252 adjusts the angle of the tilted wafer in the coater 2 to reduce the distribution component in the y direction and the method for adjusting the manufacturing equipment, according to the second embodiment, is completed.

By using the system and method for adjusting the manufacturing equipment, according to the second embodiment, it is possible to adjust the equipment parameters of the manufacturing equipment 20. Also, it is possible to unify the planar distribution of the depths of the manufactured via holes by using the adjusted manufacturing equipment 20.

### OTHER EMBODIMENTS

Although the invention has been described above by reference to the embodiment of the present invention, the present invention is not limited to the embodiment described above. Modifications and variations of the embodiments described above will occur to those skilled in the art, in the light of the above teachings. For example, in the first and second embodiments, the line widths of the portions of the resist pattern and the depths of the via holes are described as the examples of the sizes of the portions of the product. Alternatively, thicknesses of the portions of the insulating layer on the wafer may be measured as the sizes of the portions of the product. In this case, the planar distribution of the thicknesses of the portions of the insulating layer is unified by adjusting the equipment parameters of the manufacturing equipment 20. Also, the doses for the exposure fields on the resist layer may be adjusted to reduce the distribution components, shown in FIGS. 6-10. As described above, the present invention includes many variations of the embodiments. Therefore, the scope of the invention is defined with reference to the following claims.

What is claimed is:

1. A system for adjusting a manufacturing equipment comprising:
a measurement equipment configured to measure a plurality of sizes of portions of a product on a plane;
an approximation module configured to approximate a planar distribution of the plurality of sizes by an orthogonal polynomial as a function of coordinates on the plane;
an association module configured to associate a plurality of terms in the orthogonal polynomial with a plurality of equipment parameters of the manufacturing equipment, respectively, the manufacturing equipment manufacturing the product; and
an adjusting module configured to adjust the plurality of equipment parameters to reduce a plurality of distribution components, the plurality of distribution components composing the planar distribution approximated by the orthogonal polynomial.

2. The system of claim 1, wherein the orthogonal polynomial is a Zernike polynomial.

3. The system of claim 1, wherein the manufacturing equipment includes a spin coater.

4. The system of claim 3, wherein the plurality of equipment parameters include at least one of a rotational acceleration, a rotational velocity, a rotation time, an angle of a fixed wafer to be coated with a solution, an amount of the solution, and a sucking force to hold the wafer.

5. The system of claim 1, wherein the manufacturing equipment includes an exposure tool.

6. The system of claim 5, wherein the plurality of equipment parameters include at least one of an illumination condition, a polarization direction of a light, a coherence factor, a numerical aperture, a depth of focus, a focal length, an aberration, and an angle of a tilted wafer coated with a resist layer to be exposed.

7. The system of claim 1, wherein the manufacturing equipment includes a heater.

8. The system of claim 7, wherein the plurality of equipment parameters include at least one of a temperature, a baking position, a humidity, a baking velocity, a baking time, and a wind velocity.

9. The system of claim 1, wherein the manufacturing equipment includes a developing tool.

10. The system of claim 9, wherein the plurality of equipment parameters include at least one of an amount of a developing solution, a temperature, a spray condition of the developing solution, and a developing time.

11. The system of claim 1, wherein the association module ranks the plurality of terms, based on each value of a plurality of expansion coefficients in the plurality of terms.

12. The system of claim 1, wherein the association module ranks the plurality of equipment parameters, based on each adjustable range of the plurality of equipment parameters.

13. A method for adjusting a manufacturing equipment comprising:
measuring a plurality of sizes of portions of a product on a plane;
approximating a planar distribution of the plurality of sizes by an orthogonal polynomial as a function of coordinates on the plane;
associating a plurality of terms in the orthogonal polynomial with a plurality of equipment parameters of the manufacturing equipment, respectively, the manufacturing equipment manufacturing the product; and
adjusting the plurality of equipment parameters to reduce a plurality of distribution components composing the planar distribution approximated by the orthogonal polynomial.

14. The method of claim 13, wherein the orthogonal polynomial is a Zernike polynomial.

15. The method of claim 13, wherein the manufacturing equipment includes an exposure tool.

16. The method of claim 15, wherein the plurality of equipment parameters include at least one of an illumination condition, a polarization direction of a light, a coherence factor, a numerical aperture, a depth of focus, a focal length, an aberration, and an angle of a tilted wafer coated with a resist layer to be exposed.

17. The method of claim 13, wherein the manufacturing equipment includes a heater.

18. The method of claim 17, wherein the plurality of equipment parameters include at least one of a temperature, a baking position, a humidity, a baking velocity, a baking time, and a wind velocity.

19. A method for manufacturing a semiconductor device comprising:
measuring a plurality of sizes of portions of a product on a plane;
approximating a planar distribution of the plurality of sizes by an orthogonal polynomial as a function of coordinates on the plane;
associating a plurality of terms in the orthogonal polynomial with a plurality of equipment parameters of the manufacturing equipment, respectively, the manufacturing equipment manufacturing the product;
adjusting the plurality of equipment parameters to reduce a plurality of distribution components composing the planar distribution approximated by the orthogonal polynomial; and
manufacturing the semiconductor device by the manufacturing equipment of which the plurality of equipment parameters are adjusted.

20. The method of claim 19, wherein the orthogonal polynomial is a Zernike polynomial.
